(19) United States
(12) Patent Application Publication
(10) Pub. No.: US 2015/0357527 A1
(43) Pub. Date: Dec. 10, 2015

(54) METHOD FOR MANUFACTURING LIGHT-EMITTING DEVICE, AND LIGHT-EMITTING DEVICE

(71) Applicant: SHARP KABUSHIKI KAISHA, Osaka-shi, Osaka (JP)

(72) Inventors: Kazuo TAMAKI, Osaka-shi (JP); Masayuki OHTA, Osaka-shi (JP); Shinji YAMAGUCHI, Osaka-shi (JP); Kenichi KURITA, Osaka-shi (JP); Masaki TATSUMI, Osaka-shi (JP)

(73) Assignee: SHARP KABUSHIKI KAISHA, Osaka-shi, Osaka (JP)

(21) Appl. No.: 14/653,351

(22) PCT Filed: Dec. 13, 2013
(86) PCT No.: PCT/JP2013/083430

§ 371 Date: Jun. 18, 2015

(30) Foreign Application Priority Data
Jan. 31, 2013 (JP) 2013-016554

(51) Int. Cl. H01L 33/48; H01L 33/62

(52) U.S. Cl. CPC H01L 33/486; H01L 33/62; H01L 2933/0033; H01L 2933/0066; H01L 2933/0016

(57) ABSTRACT

A method for manufacturing a light-emitting device, the method comprising: a frame formation step of forming a frame such that a height from a surface of a terminal to which a wire is connected to an upper rim of the frame is smaller than a height from a top surface of a light-emitting element to the upper rim of the frame; a bump formation step of forming a bump on an electrode of the light-emitting element to which the wire is connected; a first bonding step of bonding, first, one end of the wire to the terminal; a second bonding step of bonding, subsequently, the other end of the wire to the bump; and a sealing step of sealing the light-emitting element by filling a sealing material inside the frame.

### TECHNICAL FIELD

The present invention relates to a method for manufacturing a light-emitting device, and to a light-emitting device manufactured by the method.

### BACKGROUND ART

Conventionally, light-emitting devices that use a light-emitting element, for example an LED (light-emitting diode) chip or the like, are known. In a light-emitting device using an LED chip, for the purposes of protecting the LED chip itself and a wire that is electrically connected to the LED chip, improving extraction efficiency of the light emitted by the LED chip, and dispersing phosphors, the LED chip is covered by a sealing material comprising transparent resin. The light emitted by the LED chip is transmitted through the sealing material and is emitted to the outside from a surface (light extraction surface) of the sealing material. One such conventional light-emitting device is described in Patent Document 1.

The light-emitting device (a light-emitting element package) described in Patent Document 1 has a light-emitting element mounted on a substrate (reflective cup) located in a bottom part of a frame (body), and has the light-emitting element electrically connected via a wire to another substrate separated from the light-emitting element. Generally, both ends of the wire are bonded to the light-emitting element and the substrate respectively by bonding, which involves, first, bonding (first bonding) one end of the wire to the light-emitting element and, subsequently, bonding (second bonding) the other end of the wire to the substrate separated from the light-emitting element.

### LIST OF CITATIONS

### Patent Literature

Patent Document 1: JP-A-2011-254080

### SUMMARY OF THE INVENTION

1. Technical Problem

Here, in the first bonding of a wire, it is known that a neck area right above a bonding spot of the wire is recrystallized. It is also known that, in the recrystallized region of the wire, the metal is brittle and breaks easily.

On the other hand, as a sealing material to cover a light-emitting element, a material with a comparatively large thermal expansion coefficient is sometimes used. The light-emitting device is considered to be subjected to change, or repeated change, in temperature due to the external environment or lighting/extinction of the light-emitting element. As the sealing material repeatedly expands and contracts due to change in temperature, the wire may receive repeated stress. The repeated stress may adversely affect the recrystallization region of a wire, causing the wire to break more easily.

These and other inconveniences are feared to worsen with the increasing size of light-emitting devices, that is, with the increasing amount of sealing material and length of wires.

Devised against the background discussed above, an object of the present invention is to provide a method for manufacturing a light-emitting device which helps minimize breakage of a wire bonded to the light-emitting device, and to provide a light-emitting device manufactured by the method.

2. Means for Solving the Problem

To achieve the above object, according to one aspect of the present invention, a method for manufacturing a light-emitting device includes: a frame formation step of forming a frame such that it includes a mounting substrate on which a light-emitting element is mounted and a terminal separated from the mounting substrate and electrically connected to the light-emitting element by a wire, and such that the height from a surface of the terminal to which the wire is connected to the upper rim of the frame is smaller than the height from the top surface of the light-emitting element to the upper rim of the frame; a bump formation step of forming a bump on an electrode of the light-emitting element to which the wire is connected; a first bonding step of bonding, first, one end of the wire to the terminal; a second bonding step of bonding, subsequently, the other end of the wire to the bump; and a sealing step of sealing the light-emitting element by filling a sealing material inside the frame.

With this configuration, it is possible to make the thickness of the sealing material over the first bonding spot of the wire smaller than the thickness of the sealing material over the second bonding spot. This helps reduce the effect of expansion/contraction of the sealing material on the first bonding spot of the wire, that is, a recrystallization region of the wire.

In the above-described method for manufacturing a light-emitting device, preferably, the bump formation step involves forming the bump on an n-electrode of the light-emitting element.

According to another aspect of the present invention, a light-emitting device is manufactured by the above-described method.

3. Advantageous Effects of the Invention

According to the present invention, it is possible to provide a method for manufacturing a light-emitting device which helps minimize breakage of a wire bonded to a light-emitting device, and to provide a light-emitting device manufactured by the method.

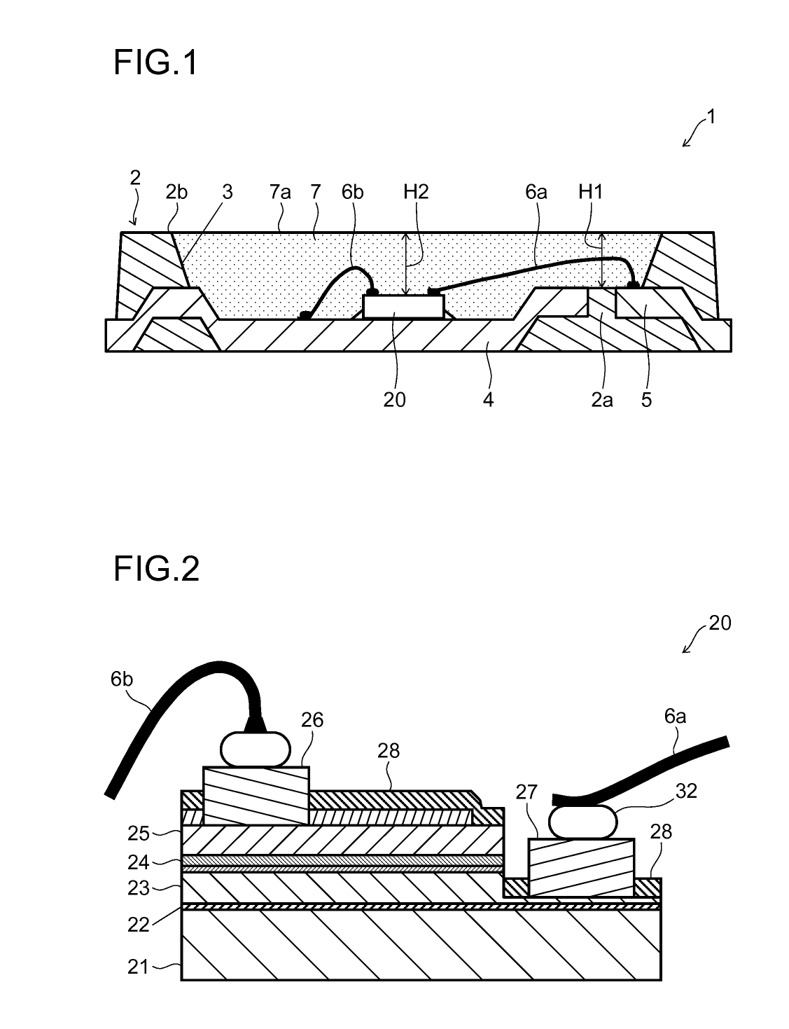

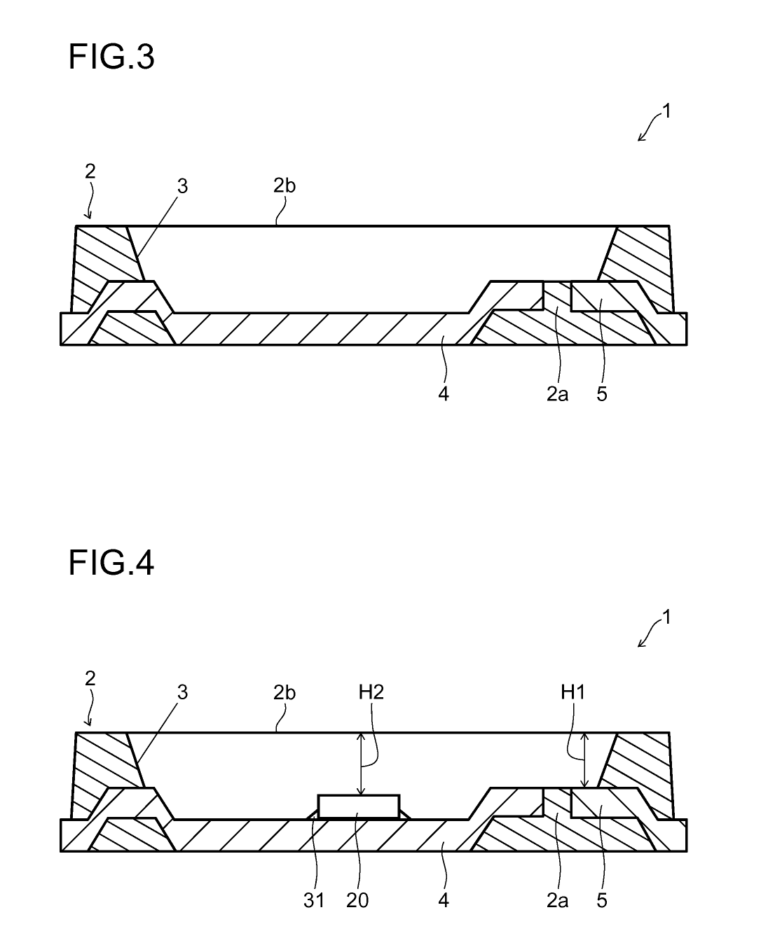

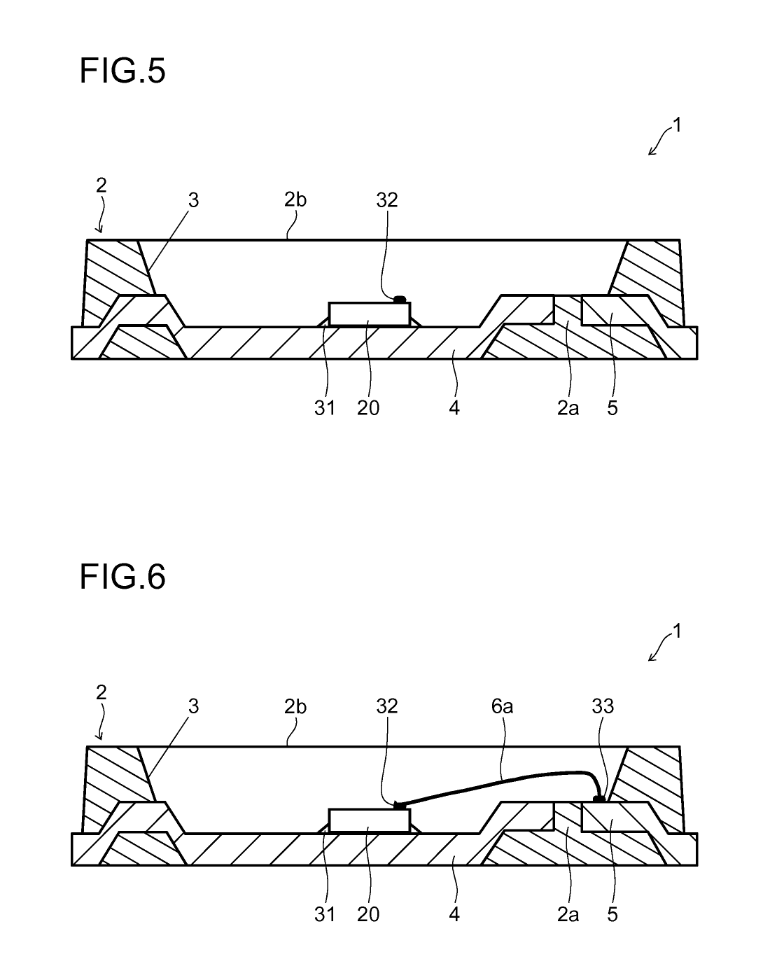

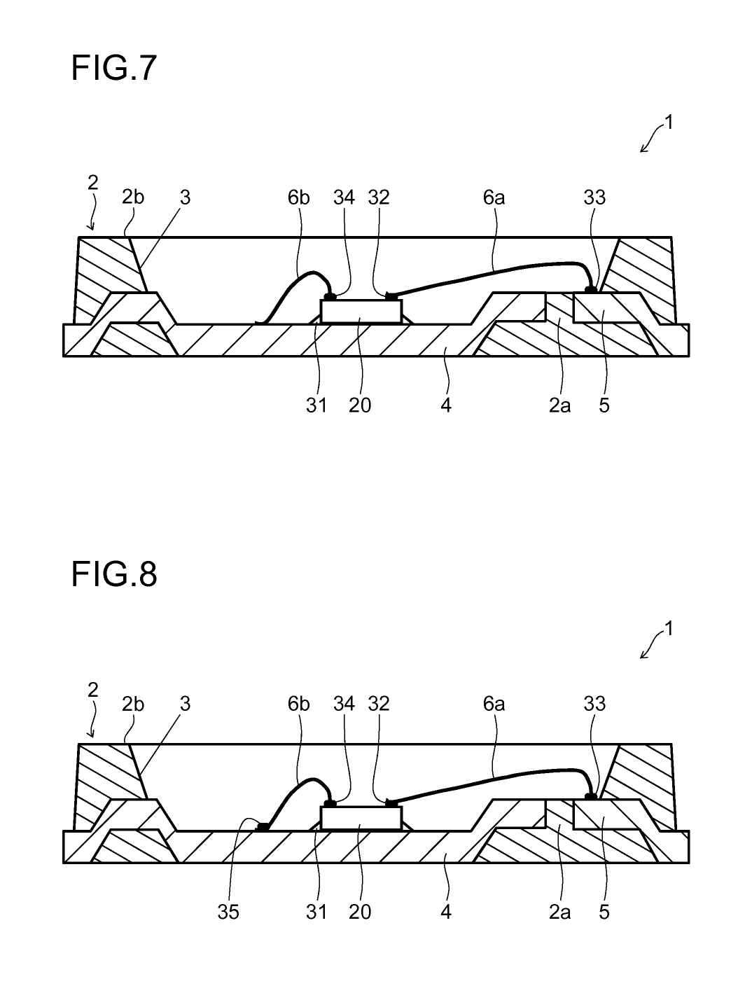

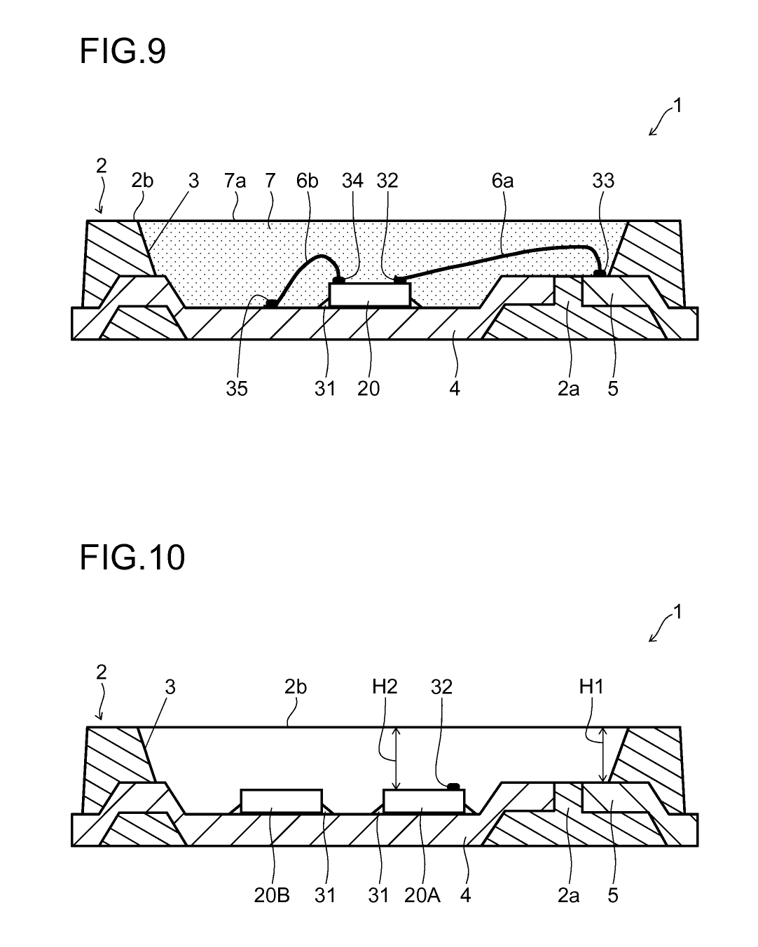

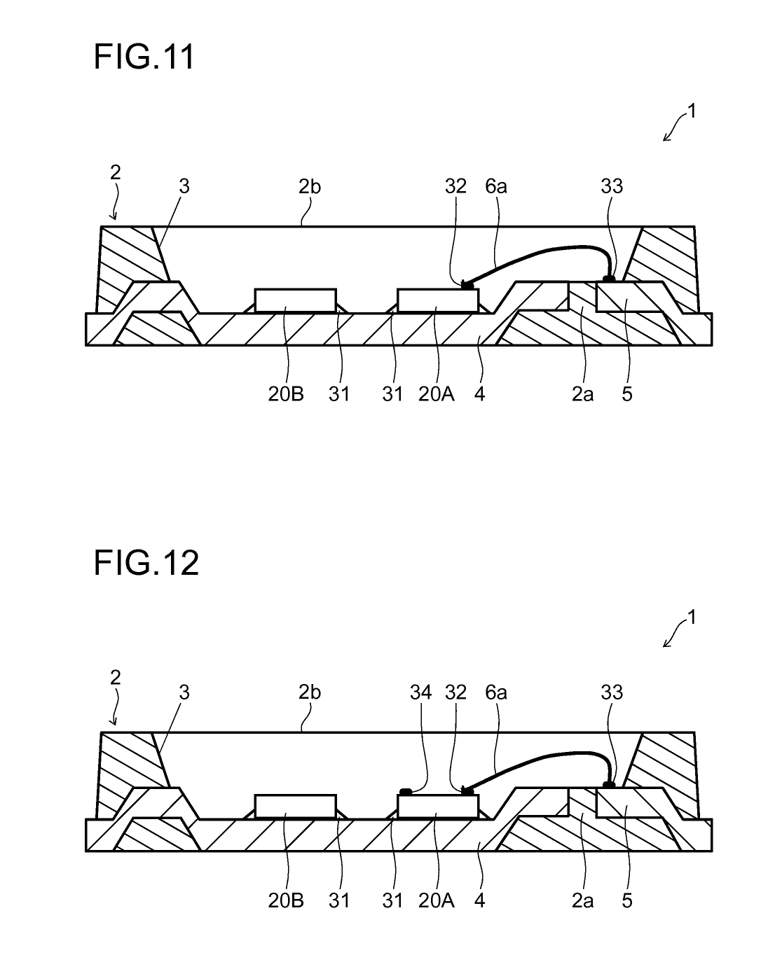

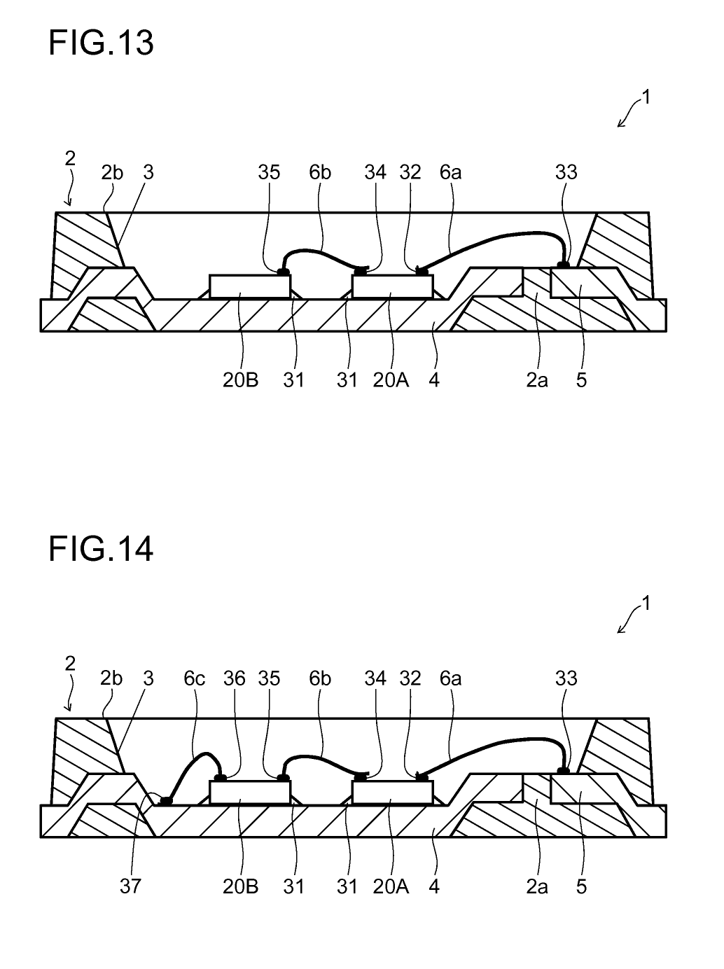

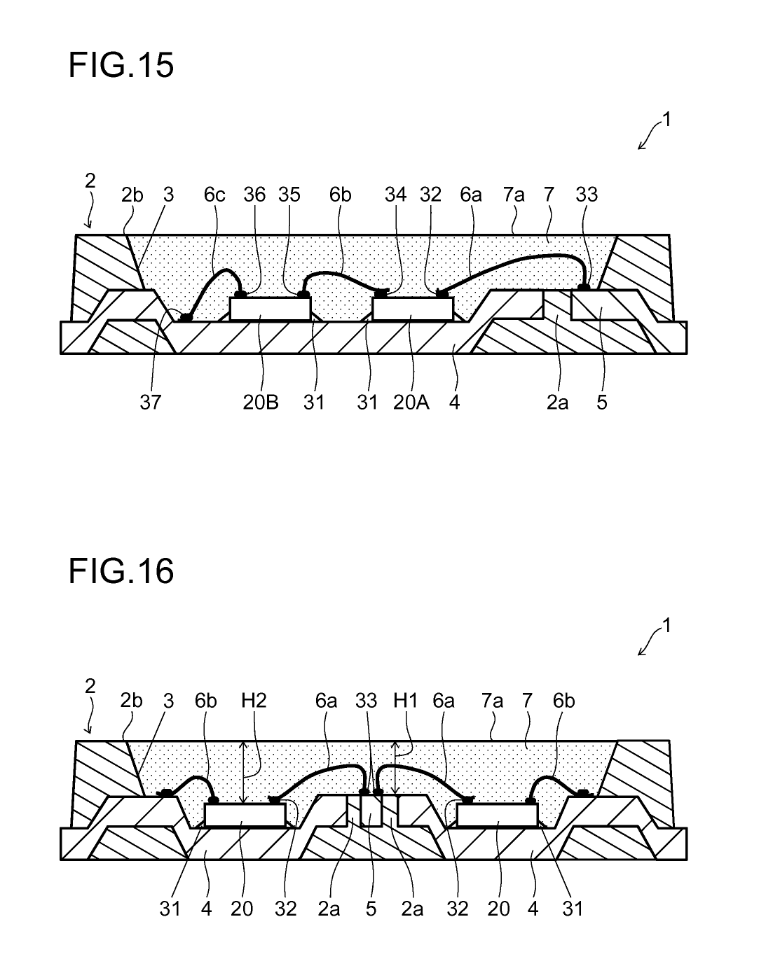

### BRIEF DESCRIPTION OF DRAWINGS

[FIG. 1] A sectional view of a light-emitting device embodying the present invention.

[FIG. 2] A sectional view of a light-emitting element of the light-emitting device embodying the present invention.

[FIG. 3] A sectional view illustrating a method for manufacturing a light-emitting device according to a first example of the present invention.

[FIG. 4] A sectional view illustrating a method for manufacturing the light-emitting device according to the first example of the present invention.

[FIG. 5] A sectional view illustrating a method for manufacturing the light-emitting device according to the first example of the present invention.

[FIG. 6] A sectional view illustrating a method for manufacturing the light-emitting device according to the first example of the present invention.

[FIG. 7] A sectional view illustrating a method for manufacturing the light-emitting device according to the first example of the present invention.

[FIG. 8] A sectional view illustrating a method for manufacturing the light-emitting device according to the first example of the present invention.

[FIG. 9] A sectional view illustrating a method for manufacturing the light-emitting device according to the first example of the present invention.

[FIG. 10] A sectional view illustrating a method for manufacturing a light-emitting device according to a second example of the present invention.

[FIG. 11] A sectional view illustrating a method for manufacturing the light-emitting device according to the second example of the present invention.

[FIG. 12] A sectional view illustrating a method for manufacturing the light-emitting device according to the second example of the present invention.

[FIG. 13] A sectional view illustrating a method for manufacturing the light-emitting device according to the second example of the present invention.

[FIG. 14] A sectional view illustrating a method for manufacturing the light-emitting device according to the second example of the present invention.

[FIG. 15] A sectional view illustrating a method for manufacturing the light-emitting device according to the second example of the present invention.

[FIG. 16] A sectional view illustrating a method for manufacturing a light-emitting device according to a third example of the present invention.

### DESCRIPTION OF EMBODIMENTS

Hereinafter, embodiments of the present invention will be described with reference to FIGS. 1 to 16.

First, a structure of a light-emitting device embodying the present invention will be described with reference to FIGS. 1 and 2. FIG. 1 is a sectional view of the light-emitting device and FIG. 2 is a sectional view of a light-emitting element in the light-emitting device.

As shown in FIG. 1, the light-emitting device 1 is provided with a light-emitting element 20 mounted on a frame 2. The light-emitting element 20 is, for example, an LED chip formed using a semiconductor. The type of the semiconductor used in the LED chip is determined as necessary, for example, based on a desired wavelength or the like of the light emitted by the LED chip. The LED chip may be an LED chip of any wavelength, such as ultraviolet, blue, green, red, or infrared.

As shown in FIG. 2, in the light-emitting element 20, for example, crystals of a plurality of semiconductor layers are grown on a top surface of an element substrate 21 made of sapphire. On the element substrate 21, there are stacked, in order from the substrate side, a buffer layer 22, an n-type semiconductor layer 23, an active layer 24 which serves as a light-emitting layer, and a p-type semiconductor layer 25. A p-electrode 26 is provided on the p-type semiconductor layer 25.

A part of the n-type semiconductor layer 23, the active layer 24, and the p-type semiconductor layer 25 are etched into a mesa shape, and thus part of the n-type semiconductor layer 23 is exposed upward. An n-electrode 27 is provided on the exposed part of the n-type semiconductor layer 23. Over most of the top surface of the light-emitting element 20, a protective film 28 is provided so as to expose the p-electrode 26 and the n-electrode 27.

As shown in FIG. 1, the frame 2 is substantially rectangular in outline, and has a depression 3. The depression 3 has side surfaces that are so inclined as to be increasingly wide open from inside the frame 2 towards the top surface of the frame 2 in FIG. 1, and forms an opening at the top surface of the frame 2. The light-emitting element 20 is arranged on an inner bottom surface of the depression 3.

Part of the light emitted by the light-emitting element 20 is reflected on the inclined side surfaces of the depression 3. To improve light extraction efficiency with the light-emitting device 1, the frame 2 is preferably made of a material with high reflectance; for example, it is possible to use rigid white resin such as polyphthalamide resin or polyethylene terephthalate resin, or ceramic comprising a sintered product of aluminum oxide (Al₂O₃).

The frame 2 is laid with a mounting substrate 4 and a terminal 5. The mounting substrate 4 and the terminal 5 are formed in a pair to serve specifically as positive and negative electrodes, and are separated from each other across an insulating portion 2a which is a part of the frame 2. The mounting substrate 4 and the terminal 5 are both arranged such that one end part of each is located on the inner bottom surface of the depression 3. The mounting substrate 4 and the terminal 5 can be formed integrally with the frame 2.

The light-emitting element 20 is mounted on the top surface of the mounting substrate 4 in FIG. 1, substantially in a central part of it in the horizontal direction of the frame 2. The light-emitting element 20 is electrically connected to the terminal 5 and the mounting substrate 4 by wires 6a and 6b. Here, the mounting substrate 4 and the terminal 5 are formed such that the height H1 from the surface of the terminal 5 to which the wire 6a is connected to an upper rim 2b of the frame 2 is smaller than the height H2 from the top surface of the light-emitting element 20 to the upper rim 2b of the frame 2.

The light-emitting element 20 and the wires 6a and 6b are covered, from around, by a sealing material 7. The depression 3 in the frame 2 is filled with the sealing material 7. Light emitted by the light-emitting element 20 emerges from a light extraction surface 7a which is a top surface of the sealing material 7 exposed to the outside out of the depression 3 and which is thus the top surface in FIG. 1. The sealing material 7 is, for example, thermosetting epoxy resin or silicone resin. This helps improve the reliability and transparence of the sealing material 7, and helps improve light extraction efficiency of the light-emitting device 1. Additives such as a phosphor and a dispersant may be mixed in the sealing material 7.

### Example 1

Now, a first practical example of a method for manufacturing the light-emitting device 1 will be described with reference to FIGS. 3 to 9. FIGS. 3 to 9 are sectional views illustrating the method for manufacturing the light-emitting device 1. In the course of the description of the first example, FIGS. 1 and 2 will also be referred to as necessary.

In the first practical example of the method for manufacturing the light-emitting device 1, first, in a frame formation step as shown in FIG. 3, the frame 2 is formed integrally with the mounting substrate 4 and the terminal 5 by, for example, insert molding. The mounting substrate 4 and the terminal 5 are separated from each other across the insulating portion 2a. The mounting substrate 4 and the terminal 5 are, as shown in FIGS. 3 and 4, formed such that the height H1 from the surface of the terminal 5 to which the wire 6a (see FIG. 1) is connected to the upper rim 2b of the frame 2 is smaller than the height H2 from the top surface of the light-emitting element 20 to the upper rim 2b of the frame 2.

Next, in an element mounting step as shown in FIG. 4, a die bonding material 31 is supplied to a surface of the mounting substrate 4 exposed on the inner bottom surface of the depression 3 in the frame 2, and then, the light-emitting element 20 is mounted on top of it. In this way, the light-emitting element 20 is fixed on the surface of the mounting substrate 4.

Next, in a bump formation step as shown in FIG. 5, a bump 32 is formed on the n-electrode 27 (see FIG. 2) of the light-emitting element 20. The bump 32 is for the wire 6a which extends towards the terminal 5 separated from the light-emitting element 20 across the insulating portion 2a.

Next, in a bonding step as shown in FIG. 6, the wire 6a is bonded for electrically connecting the light-emitting element 20 to the terminal 5 over a space between them. In the bonding step with respect to the wire 6a, there are performed a first bonding step where, first, for example, a ball 33 is formed at one end of the wire 6a and is bonded to the terminal 5; and a second bonding step where, subsequently, the other end of the wire 6a is bonded to the bump 32 on the light-emitting element 20.

Subsequently, in a bonding step as shown in FIGS. 7 and 8, the wire 6b for electrically connecting together the p-electrode 26 (see FIG. 2) of the light-emitting element 20 and the mounting substrate 4 is bonded to each of them. In the bonding step with respect to the wire 6b, first, for example, a ball 34 is formed at one end of the wire 6b and is bonded to the p-electrode 26 of the light-emitting element 20, and subsequently, for example, a ball 35 is formed at the other end of the wire 6b and is bonded to the mounting substrate 4.

Next, in a sealing step as shown in FIG. 9, the depression 3 inside the frame 2 is filled with the sealing material 7. A predetermined amount of sealing material 7 is poured in drops towards the light-emitting element 20 by use of, for example, a dispenser or the like. Thus, the light-emitting element 20 is sealed in the sealing material 7.

### Example 2

Now, a second practical example of the method for manufacturing the light-emitting device 1 will be described with reference to FIGS. 10 to 15. FIGS. 10 to 15 are sectional views illustrating the method for manufacturing the light-emitting device 1. This practical example has a basic configuration similar to that of the first practical example described previously with reference to FIGS. 3 to 9, and thus such components as are common to the first and this practical example are identified by the same reference signs as previously used, and some of the steps are omitted from illustration.

In the second practical example, the light-emitting device 1 has, as shown in FIG. 15, two light-emitting elements 20A and 20B mounted on the mounting substrate 4. The two light-emitting elements 20A and 20B are electrically connected in series between the mounting substrate 4 and the terminal 5 by use of wires 6a, 6b, and 6c.

In the second practical example of the method for manufacturing the light-emitting device 1, first, in a frame formation step, the frame 2 is formed integrally with the mounting substrate 4 and the terminal 5 by, for example, insert molding (see FIG. 10). The mounting substrate 4 and the terminal 5 are separated from each other across the insulating portion 2a. The mounting substrate 4 and the terminal 5 are, as shown in FIG. 10, formed such that the height H1 from the surface of the terminal 5 to which the wire 6a (see FIG. 11) is connected to the upper rim 2b of the frame 2 is smaller than the height H2 from the top surface of the light-emitting elements 20A and 20B to the upper rim 2b of the frame 2.

Next, in an element mounting step, the die bonding material 31 is supplied to the surface of the mounting substrate 4 exposed on the inner bottom surface of the depression 3 in the frame 2, and then, the two light-emitting elements 20A and 20B are mounted on top of it (see FIG. 10). In this way, the light-emitting elements 20A and 20B are fixed on the surface of the mounting substrate 4.

Next, in a first bump formation step, the bump 32 is formed (see FIG. 10) on the n-electrode 27 (see FIG. 2) of the light-emitting element 20A closer to the terminal 5. The bump 32 is for the wire 6a which extends towards the terminal 5 separated from the light-emitting element 20A across the insulating portion 2a.

Next, in a bonding step as shown in FIG. 11, the wire 6a is bonded for electrically connecting the light-emitting element 20A to the terminal 5 over a space between them. In the bonding step with respect to the wire 6a, there are performed a first bonding step where, first, for example, the ball 33 is formed at one end of the wire 6a and is bonded to the terminal 5; and a second bonding step where, subsequently, the other end of the wire 6a is bonded to the bump 32 on the light-emitting element 20A.

Next, in a second bump formation step as shown in FIG. 12, a bump 34 is formed on the p-electrode 26 (see FIG. 2) of the light-emitting element 20A closer to the terminal 5. The bump 34 is for the wire 6b which electrically connects together the light-emitting elements 20A and 20B which are mounted on the mounting substrate 4.

Next, in a bonding step as shown in FIG. 13, the wire 6a is bonded for electrically connecting together the light-emitting elements 20A and 20B. In the bonding step with respect to the wire 6b, first, for example, a ball 35 is formed at one end of the wire 6b and is bonded to the n-electrode 27 (see FIG. 2) of the light-emitting element 20B, and subsequently, the other end of the wire 6b is bonded to the bump 34 on the p-electrode 26 of the light-emitting element 20A.

Subsequently, in a bonding step as shown in FIG. 14, the wire 6c for electrically connecting together the p-electrode 26 (see FIG. 2) of the light-emitting element 20B farther away from the terminal 5 and the mounting substrate 4 are bonded to each of them. In the bonding step with respect to the wire 6c, first, for example, a ball 36 is formed at one end of the wire 6c and is bonded to the p-electrode 26 of the light-emitting element 20, and subsequently, for example, a ball 37 is formed at the other end of the wire 6c and is bonded to the mounting substrate 4.

Next, in a sealing step as shown in FIG. 15, the depression 3 inside the frame 2 is filled with the sealing material 7. A predetermined amount of sealing material 7 is poured in drops towards the light-emitting elements 20A and 20B by use of, for example, a dispenser or the like. Thus, the light-emitting elements 20A and 20B are sealed in the sealing material 7.

### Example 3

Now, a third practical example of the method for manufacturing the light-emitting device 1 will be described with reference to FIG. 16. FIG. 16 is a sectional view illustrating the method for manufacturing the light-emitting device 1. This practical example has a basic configuration similar to that of the first practical example described previously with reference to FIGS. 3 to 9 and that of the second practical example described previously with reference to FIGS. 10 to 15, and thus such components as are common to the first, the second, and this practical example are identified by the same reference signs as previously used, and some of the steps are omitted from illustration.

In the third practical example, the light-emitting device 1 has, as shown in FIG. 16, two light-emitting elements 20 mounted on the mounting substrate 4. The two light-emitting elements 20 are, on a one-by-one basis, connected electrically in series between the mounting substrate 4 and the terminal 5 by use of wires 6a and 6b.

In the third practical example of the method for manufacturing the light-emitting device 1, first, in a frame formation step, the frame 2 is formed such that two mounting substrates 4 provided respectively on the right and left in FIG. 16 and the terminal 5 provided at the center in the left/right direction in FIG. 16 are separated from each other across the insulating portion 2a. The two mounting substrates 4 and the terminal 5 are also formed such that the height H1 from the surface of the terminal 5 to which the wire 6a is connected to the upper rim 2b of the frame 2 is smaller than the height H2 from the top surface of the light-emitting elements 20 to the upper rim 2b of the frame 2.

Next, in an element mounting step, the die bonding material 31 is supplied to the surface of each of the two mounting substrates 4 exposed on the inner bottom surface of the depression 3 in the frame 2, and then, the two light-emitting elements 20 are mounted on top of them respectively. In this way, the two light-emitting elements 20 are fixed on the surfaces of the mounting substrates 4 respectively.

Next, in a bump formation step, the bumps 32 are formed on the n-electrodes 27 (see FIG. 2) of the two light-emitting elements 20 respectively. The bumps 32 are for the wires 6a which extend towards the terminal 5 separated from each of the two light-emitting elements 20 across the insulating portion 2a.

Next, in a bonding step, the two wires 6a are bonded for electrically connecting the two light-emitting elements 20, respectively, to the terminal 5 over a space between them. In the bonding step with respect to the wires 6a, there are performed a first bonding step where, first, for example, the balls 33 are formed at one end of the wires 6a and are bonded to the terminal 5; and a second bonding step where, subsequently, the other end of the wires 6a are bonded to the bumps 32 on the light-emitting elements 20. Subsequently, in the bonding step, the wires 6b for electrically connecting together, on a one-by-one basis, the p-electrodes 26 (see FIG. 2) of the two light-emitting elements 20 and the two mounting substrates 4 are bonded to each of them.

Next, in a sealing step, the depression 3 inside the frame 2 is filled with the sealing material 7. A predetermined amount of sealing material 7 is poured in drops towards the light-emitting elements 20 by use of, for example, a dispenser or the like. Thus, both of the light-emitting elements 20 are sealed in the sealing material 7.

As described above, the method for manufacturing the light-emitting device 1 includes: a frame formation step of forming a frame 2 such that it includes a mounting substrate 4 on which a light-emitting element 20 is mounted and a terminal 5 separated from the mounting substrate 4 and electrically connected to the light-emitting element 20 by a wire 6a, and such that the height H1 from the surface of the terminal 5 to which the wire 6a is connected to the upper rim 2a of the frame 2 is smaller than the height H2 from the top surface of the light-emitting element 20 to the upper rim 2a of the frame 2; a bump formation step of forming a bump 32 on an electrode of the light-emitting element 20 to which the wire 6a is connected; a first bonding step of bonding, first, one end of the wire 6a to the terminal 5; a second bonding step of bonding, subsequently, the other end of the wire 6a to the bump 32; and a sealing step of sealing the light-emitting element 20 by filling a sealing material 7 inside the frame 2. Thus, it is possible to make the thickness (H1) of the sealing material 7 over the first bonding spot of the wire 6a smaller than the thickness (H2) of the sealing material 7 over the second bonding spot. This helps reduce the effect of expansion/contraction of the sealing material 7 on the first bonding spot of the wire 6a, that is, a recrystallization region of the wire 6a.

A load is applied to the second bonding spot of the wire 6a twice, that is, when the bump 32 is formed and when the second bonding is performed, and this may inconveniently cause breakage under the p-electrode 26, which is formed on top of a multilayer structure. According to the method for manufacturing the light-emitting device 1, in the bump formation step, the bump 32 is formed on the n-electrode 27 of the light-emitting element 20. In this way, it is possible to prevent the light-emitting element 20 from being damaged.

Moreover, owing to the light-emitting device 1 being manufactured by the above method, it is possible to obtain a light-emitting device 1 with a reduced effect of expansion/contraction of the sealing material 7 on the recrystallization region of the wire 6a. This helps improve the resistance of the light-emitting device 1 to change, or repeated change, in temperature due to the external environment or heat from the device itself. Thus, even with a relatively large amount of sealing material 7, it is possible to suppress breakage of the wire 6a, and thus to make the light-emitting device 1 larger.

According to the configuration of the above-described embodiments of the present invention, it is possible to provide a method for manufacturing a light-emitting device 1 that helps minimize breakage of a wire 6a to which a light-emitting element 20 is connected, and to provide a light-emitting device 1 manufactured by the method.

The embodiments of the present invention described above are in no way meant to limit the scope of the present invention, which thus allows for many modifications and variations within the spirit of the present invention.

### INDUSTRIAL APPLICABILITY

The present invention finds application in methods for manufacturing a light-emitting device with a light-emitting element covered from around by a sealing material and light-emitting devices manufactured by the methods.

### LIST OF REFERENCE SIGNS

1 light-emitting device

2 frame

2a insulating portion

2b upper rim

3 depression

4 mounting substrate

5 terminal

6a wire

7 sealing material

7a light extraction surface

20 light-emitting element

26 p-electrode

27 n-electrode

32 bump

1. A method for manufacturing a light-emitting device, the method comprising:
a frame formation step of forming a frame such that the frame includes a mounting substrate on which a light-emitting element is mounted and a terminal separated from the mounting substrate and electrically connected to the light-emitting element by a wire, and such that a height from a surface of the terminal to which the wire is connected to an upper rim of the frame is smaller than a height from a top surface of the light-emitting element to the upper rim of the frame;
a bump formation step of forming a bump on an electrode of the light-emitting element to which the wire is connected;
a first bonding step of bonding, first, one end of the wire to the terminal;
a second bonding step of bonding, subsequently, the other end of the wire to the bump; and
a sealing step of sealing the light-emitting element by filling a sealing material inside the frame.

2. The method of claim 1,
wherein the bump formation step involves forming the bump on an n-electrode of the light-emitting element.

3. A light-emitting device manufactured by the method of claim 1.

4. A light-emitting device manufactured by the method of claim 2.
